(19) United States
(12) Patent Application Publication
(10) Pub. No.: US 2024/0107739 A1
(43) Pub. Date: Mar. 28, 2024

(54) DYNAMIC RANDOM-ACCESS MEMORY DEVICE AND METHOD OF FABRICATING SAME

(71) Applicant: IMEC VZW, Leuven (BE)

(72) Inventors: Nouredine Rassoul, Braine le Chateau (BE); Hyungrock Oh, Brussels (BE); Romain Delhougne, Haacht (BE); Gouri Sankar Kar, Leuven (BE); Attilio Belmonte, Schaerbeek (BE); Kaustuv Banerjee, Heverlee (BE); Mohit Gupta, Heverlee (BE)

(21) Appl. No.: 18/472,122

(22) Filed: Sep. 21, 2023

(30) Foreign Application Priority Data
Sep. 23, 2022 (EP) 22197499.1

(51) Int. Cl. H10B 12/00

(52) U.S. Cl. CPC H10B 12/00

(57) ABSTRACT

A memory device configured as a dynamic random access memory is provided, comprising a first semiconductor device layer comprising a first bit cell and a second semiconductor device layer comprising a second DRAM bit cell. Further, at least one of a first and second interconnecting structure is provided, the first interconnecting structure extending vertically between the first and second semiconductor device layer and being arranged to form a write word line common to the gate terminal of the write transistors of the first and second bit cells, and the second interconnecting structure extending vertically between the first and second semiconductor device layer and being arranged to form a read word line common to a first source/drain terminal of the read transistors of the first and second bit cells.

### CROSS-REFERENCE TO RELATED APPLICATIONS

This application claims foreign priority to European Application No. 22197499.1, filed Sep. 23, 2022, which is incorporated by reference herein in its entirety.

### BACKGROUND

### Field

The disclosed technology relates to a memory device for a dynamic random-access memory (DRAM) as well as to a method for forming such a memory device.

### Description of the Related Technology

Dynamic random-access memory (DRAM) is a type of random-access memory in which each bit cell traditionally includes a capacitor for storing a bit of data and a transistor for accessing the capacitor. The level of charge on the capacitor determines whether that particular bit cell includes a logical “1” or “0”. The bit cells are typically arranged in a two-dimensional array, in which each row is connected to a respective word line, and each column is connected to a respective bit line. The word lines are used for addressing the bit cells of a specific row, whereas the bit lines are used for reading and writing the data on the individual bit cells of the addressed row.

The strive for reduced bit cell area and increased circuit density has led to a demand for capacitors with a reduced (e.g., smaller) footprint. A particular challenge is associated with the design of the capacitor, as reducing its physical dimensions may lead to a reduced capacitance, which can reduce the signals associated with the operation of the bit cell. Additionally, it can also introduce increased geometrical complexity, thereby reducing the yield. Another attempt to increase the circuit density has therefore been to introduce a capacitorless DRAM, in which the parasitic capacitance of the read transistor serves as the storage element.

However, there is still a need for improved DRAM technologies that enable further reduction of the memory cell area without impairing the performance, manufacturability, and function of the DRAM device.

### SUMMARY OF CERTAIN INVENTIVE ASPECTS

The disclosed technology aims to provide a solution to the problems described above. These and other aims are achieved by various aspects in accordance with the embodiments of the disclosed technology. The objective of the disclosed technology is to provide a memory device for a DRAM, which allows for further reduction of the memory cell area without impairing the performance and function of the DRAM device. Additional and alternative objectives may be understood from the following.

According to some aspects of the disclosed technology, there is provided a memory device for a DRAM, including a substrate supporting a first semiconductor device layer, including a first DRAM bit cell, and a second semiconductor device layer, including a second DRAM bit cell. The first semiconductor device layer can be arranged between the substrate and the second semiconductor device layer. Each bit cell can include a write transistor and a read transistor. A first source/drain terminal of the write transistor can be connected to a gate of the read transistor to form a storage node of the bit cell. The memory device can further include at least one of a first interconnecting structure extending vertically between the first and second semiconductor device layer and being arranged to form a write word line common to the gate terminal of the write transistors of the first and second bit cells, and a second interconnecting structure extending vertically between the first and second semiconductor device layer and being arranged to form a read word line common to a first source/drain terminal of the read transistors of the first and second bit cells.

By stacking bit cells above the substrate, the area efficiency of the memory device can be improved since a vertical stacking direction can provide an additional scaling path compared to conventional planar memory arrays. Further, the stacked configuration may allow the terminals of each bit cell of the resulting DRAM to be accessed in a more efficient manner, as some of the terminals can be merged. While the read and write word lines are common along the vertical axis but isolated within each device layer, the design further can allow the read and write bit lines to be common to horizontal rows of bit cells and vertically isolated between the device layers. Thus, the word lines can be arranged orthogonally to the bit lines to more efficiently utilize the available cell area compared to conventional planar memory arrays or planar memory arrays that are monolithically stacked on top of each other.

The substrate can support the first and second semiconductor device layers in which the bit cells can be formed or implemented. The device layers can be extended laterally or horizontally along a main surface of the substrate. The device layers may be referred to as a back end of line (BEOL) portion of the substrate or the memory device.

The write transistor of each bit cell may be a field-effect transistor (FET). In some embodiments, the write transistor may be an n-type FET.

The read transistor of each bit cell may be a FET. In some embodiments, the read transistor may be an n-type FET.

The charge storage element of each bit cell can be formed by a parasitic capacitive coupling between a terminal of the write transistor, such as the drain, and a terminal of the read transistor, such as the gate.

As used herein, the term DRAM refers to a memory wherein data are stored by predetermined levels of charges by a capacitive charge storage element of each bit cell. In the “read mode,” one or more bit cells can be accessed in order to read out data stored by the bit cells. Conversely, in the “write mode,” one or more bit cells can be charged to a predetermined high voltage level (e.g., to store a “1”) or a predetermined low voltage level (e.g. to store a “0”) in order to write data to be stored by the bit cell.

According to some embodiments, each semiconductor layer of the memory device can include a plurality of bit cells and a horizontal read bit line, RBL, interconnecting the read transistors of each bit cell.

According to some embodiments, each semiconductor layer can include a horizontal write bit line, WBL, interconnecting the write transistors of each bit cell.

The read bit line of the first semiconductor device layer can be electrically insulated from the read bit line of the second semiconductor layer. Correspondingly, the write bit line of the first semiconductor device layer may be electrically insulated from the bit line of the second semiconductor device layer.

According to some embodiments, the write transistor and the read transistor are metal-oxide semiconductor FETs (MOSFETs). The metal-oxide transistors can lend themselves for integration in the BEOL portion (e.g., being implemented in materials which may be processed within the reduced thermal budget available during BEOL-processing). Such transistors can be associated with their relatively low off-state leakage and their BEOL compatibility. The fabrication of such devices can take advantage of the vertical dimension to enable a high system scalability along the vertical axis.

According to some aspects, there is provided a method for forming a memory device for a DRAM. The method can include a first bit cell and a second bit cell, each bit cell including a write transistor and a read transistor, wherein a first source/drain terminal of the write transistor can be connected to a gate of the read transistor to form a storage node of the bit cell. The method can include forming a first trench and a second trench, parallel to the first trench, in a stacked layer structure that can include a first sub-stack and a second sub-stack of layers. The method can also include, in the first trench, forming the write transistor of each sub-stack by laterally recessing layers of the sub-stack and forming, in the recesses, a channel structure, a gate dielectric, and gate metal of the write transistor. The method further includes forming the write word line in the first trench to interconnect the gate terminal of the write transistors of the first and second bit cells. The method can further include, in the second trench, forming the read transistor of each sub-stack by laterally recessing layers of the sub-stack and forming, in the recesses, a channel structure and a gate dielectric of the read transistor, and an isolating layer, and forming the read word line in the second trench to interconnect the first source/drain terminal of the read transistor of the first and second bit cells.

According to some embodiments, lateral recesses can be formed from the first trench and from the second trench. Each device layer can be provided with a recess from the trenches on both sides of the layer. Thereafter, the recesses formed from the first trench can be filled with a conductive material to form the horizontal read bit line, RBL, whereas the recesses formed from the second trench can be filled a conductive material to form the horizontal write bit line WBL. For each sub-stack, the RBL may be arranged to interconnect the read transistors of each of the plurality of bit cells and the WBL arranged to interconnect the write transistors of each of the plurality of bit cells.

The method outlined above generally provides the same or corresponding advantages as those discussed in connection with of the memory device. Reference is therefore made to the above discussion concerning advantages associated with the memory device, but also to the above discussion of details, embodiments and optional features with respect to the memory device, which apply correspondingly to the method as outlined above.

### BRIEF DESCRIPTION OF THE DRAWINGS

The above, as well as additional objects, features, and advantages of the disclosed technology will be better understood through the following illustrative and non-limiting detailed description of preferred embodiment of the disclosed technology, with reference to the appended drawings. In the drawings like reference numerals will be used for like elements unless stated otherwise.

FIG. 1 is a schematic illustration of a circuit layout of a memory device according to an embodiment.

FIG. 2 is a schematic illustration of a write transistor and a read transistor forming a bit cell of a memory device according to an embodiment.

FIGS. 3a and 3b are vertical cross sections through a read transistor and a write transistor, respectively, according to an exemplary transistor layout.

FIG. 4 illustrates a stack of semiconductor layers including a first and a second sub-stack, from which a memory device, according to an embodiment, is formed.

FIGS. 5-14 show intermediate structures of a memory device at different stages of the manufacturing of the memory device.

FIGS. 15a-15c show cross sections taken through different portions of a memory device according to an embodiment.

### DETAILED DESCRIPTION OF CERTAIN ILLUSTRATIVE EMBODIMENTS

Detailed embodiments of the disclosed technology will now be described with reference to the drawings. The disclosed technology should not be construed as limited to the embodiments set forth herein. Rather, these embodiments are provided by way of example so that this disclosure will convey the scope of the inventive concept to those skilled in the art.

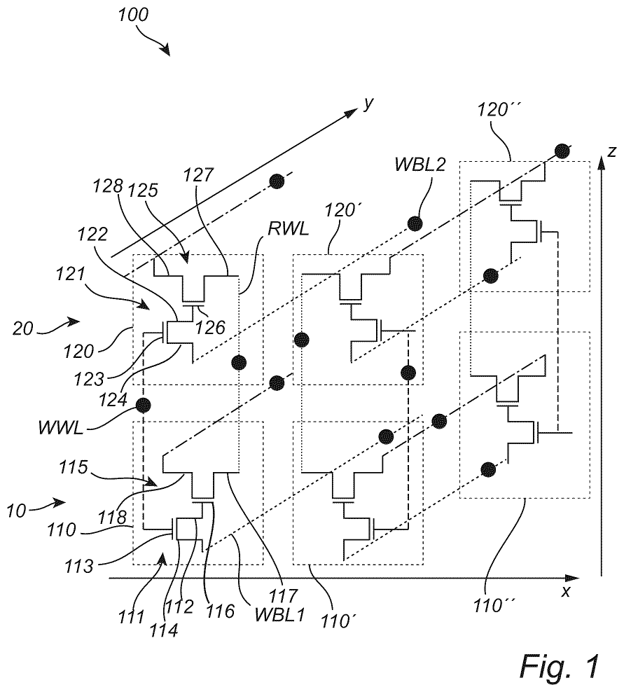

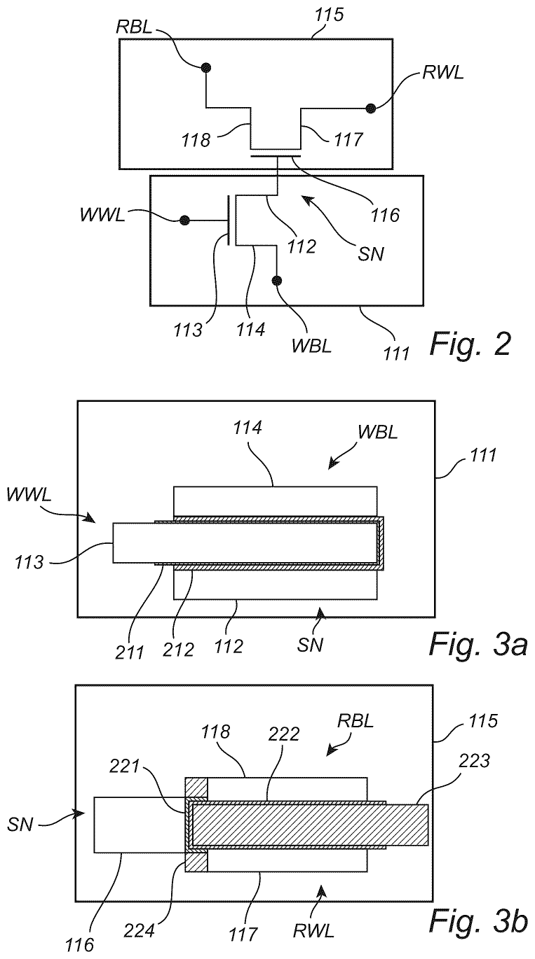

With reference to FIG. 1, a memory device 100 for a dynamic random-access memory (DRAM) is shown in FIG. 1. The device 100 can include a plurality of stacked bit cells 110, 120 arranged above each other in horizontal semiconductor device layers 10, 20. The bit cell 120 can represent a top-most bit cell of the stack, and the bit cell 110 can represent a bottom bit cell of the stack. The bit cells 110, 120, and the semiconductor device layers 10, 20 can be arranged in or between different metallization levels of a back end of line, BEOL, portion of the device 100. The layout of an example of such a bit cell 110 is illustrated in greater detail in FIG. 2.

FIG. 1 schematically shows the layout of the memory device 100, and it is appreciated that only portions of the semiconductor device layers 10, 20 forming part of the structure are shown and that the layers may extend laterally/horizontally beyond the illustrated portions. It should also be noted that for the purpose of clarity, the various layers and other features of the stacks are not drawn to scale in the appended drawings and that their relative dimensions, in particular their thickness, may differ from a physical stack. Further, as indicated in FIG. 1, it should be understood that the device 100 may include a plurality of bit cells 110′, 110″, 120′, 120″ arranged in three-dimensional bit cell arrays.

As shown in FIG. 2, a bit cell 110 can include a charge storage node, SN, a write transistor 111, and a read transistor 115. The charge storage node, SN, can be formed by a source/drain electrode 112 of the write transistor 111 and the gate 116 electrode of the read transistor 115, which are formed, or interconnected, by a common structure providing a parasitic capacitance that can be used to temporarily store a charge representing a logic state of the bit cell 110. The charge storage node, SN, may hence function as a capacitor, and the capacitance associated with the node is provided by means of the parasitic capacitance of the layout of the memory device 100.

The write transistor 111 and the read transistor 115 of each bit cell 110 may be formed at the same metallization level in the BEOL portion (e.g., in a dielectric layer between the metallization layers of adjacent metallization levels). It will, however, be appreciated that the write and read transistors 111, 115 in some examples can be formed at different levels.

As further shown in FIG. 1, each write transistor 111, 121 can include a gate electrode 113, 123 connected to a write select line or write word line WWL for addressing or selecting those specific write transistors 111, 121 during a write operation. The write word line, WWL, can be common to the vertically stacked write transistors 111, 121. and therefore extends vertically between the bit cells 110, 120 in the first and second semiconductor device layers 10, 20. Each write transistor 111, 121 can further include a first electrode and a second electrode forming source/drain electrodes 112, 114, 122, 124 of the transistor 111, 121. One of the electrodes 112, 122 of the write transistor 111, 121, such as the first one, may be connected to the gate electrode 116, 126 of the read transistor 115, 125 of the bit cell 110, 120, whereas the other one of the electrodes 114, 124 (such as the second one) may be connected to a write bit line WBL1, WBL2. Thus, the write voltage applied for charging the storage node, SN, is provided from the write bit line WBL via the write transistor 111, 121 in its selected, or closed state (e.g., conducting state). As illustrated in the exemplifying embodiment of FIG. 1, the vertically stacked bit cells 110, 120 may be commonly addressed by the common word line WWL and written using separate write bit lines, WBL 1, WBL2.

Each read transistor 115, 125 may, as already mentioned, include a gate electrode 116, 126 that is connected to the first electrode 112, 122 of the write transistor 111, 121 of the bit cell 110, 120. For example, the first electrode 112, 122 is connected to the drain of the of the write transistor 111, 121. The other electrodes of the read transistor 115, 125, that is, the first electrode 117, 127 and the second electrode 118, 128, forming source/drain electrodes of the read transistor 115, 125, can be connected to a read word line, RWL, and a read bit line, RBL 1, RBL2, respectively. As shown in FIG. 1, the read word line, RWL, can be common to the read transistors 115, 125 in the stack, thereby extending vertically between the first and second semiconductor device layers 10, 20. In its closed or conducting state, the read transistor 115, 125 may allow a read current to flow between the read common word line RWL and a read bit line, RBL 1, RBL2, respectively, thereby allowing charging or discharging of the read word line, RWL. Charging or discharging of the read word line, RWL, may be sensed and interpreted as a logic state, that is, a logic “1” or “0.”

The read word line, RWL, of a stack may be connected to a gain transistor (not shown), which may be common to the bit cells 10, 20 of each stack and configured to amplify the read-out signal and transmit it to a common or global read bit line of the DRAM.

The write transistor 111 and the read transistor 115 in the bit cell illustrated in FIG. 2 may be a FET (e.g., an n-type FET), produced in one or several a metallization levels of the BEOL portion of the memory device, as will be further described in the exemplary process flow below. It will be appreciated that the channel material may differ from the two transistor types, such that the write transistor 111 may include channel material that can be different from the one of the read transistor 115. The channel material(s) may be selected based on a targeted performance of the respective transistors 111, 115. For example, a wide band gap semiconductor material may be selected for the write transistor 111, such as a metal oxide semiconductor or doped metal semiconductor material including for example, indium gallium zinc oxide (IGZO), indium zinc oxide (IZO) or the like. For the read transistor, the channel material may be formed of Si, poly-Si, indium tin oxide (ITO), a two-dimension (2D) material, a metal oxide semiconductor or a doped metal oxide semiconductor material.

FIGS. 3a and 3b are vertical cross sections of a write transistor (FIG. 3a) and a read transistor (FIG. 3b) according to some embodiments of the inventive concept. The transistors may be similarly configured as the write transistors 111, 121, and read transistors 115, 125, respectively, discussed above in connection with FIGS. 1 and 2. Hence, the memory device 100 and bit cells 110, 120 in FIGS. 1 and 2 may be realized using the exemplary transistors in FIGS. 3a and b.

FIG. 3a shows a write transistor 111, including a first electrode 112 and a second electrode 114 forming source/drain of the transistor 111. In some examples, the first electrode 112 can form the drain, and the second electrode 114 can form the source of the transistor 111. The source and drain electrodes 112, 114 can be vertically stacked above each other, with a gate electrode 113 arranged in between. The resulting structure is thus a layered stack, with the drain electrode 112 at the bottom, the gate electrode 113 in the middle and the source electrode 114 on the top.

To form the active device, a gate dielectric layer 211 can be formed on the gate electrode 113. The gate dielectric layer 211 may be arranged to at least partly enclose the gate electrode 113. As shown in FIG. 3a, the gate dielectric layer 211 can be provided at the interface to the drain electrode 112 and the source electrode 114, as well as on a vertical end surface of the gate electrode 113 (to the right in FIG. 3a). As further illustrated in FIG. 3a, the channel region can be formed by a channel layer 212 arranged on the dielectric layer 211. As mentioned above, the gate electrode 113 can be connected to the write word line WWL and used for arranging the write transistor in its closed or conducting state, in which a write voltage can be provided from the write bit line WBL connected to the source electrode 114 to the storage note SN formed by the drain electrode 112.

FIG. 3b shows a read transistor 121, including a first electrode 117 and a second electrode 118, forming source/drain of the transistor 121. The source and drain electrodes 117, 118 can be vertically stacked above each other, with an isolating layer 223 arranged in between. Thus, the resulting structure can be a layered stack, with the first source/drain electrode 117 at the bottom, the isolating layer 223 in the middle and the second source/drain electrode 118 on the top. In some examples, the gate electrode 116 can be arranged to the side of this stacked structure (to the left in FIG. 3b), with the gate dielectric layer 221 and the channel region 222 arranged between the source/drain electrode stack and the gate electrode 116. The gate dielectric layer 221 can be arranged at least at a vertical interface between the isolating layer 223 and the gate electrode 116, whereas the channel region can be formed by a channel layer 222 deposited on the isolating layer 223. As shown in FIG. 3b, the channel layer 223 can be provided in the horizontal interfaces between the isolating layer 223 and the first and second source/drain electrodes 117, 118, as well as in the vertical interface between the gate dielectric layer 221 and the end surface of the isolating layer 223. Further, a spacer structure 224 can be provided to physically separate the gate electrode 116 and the source/drain electrodes 117, 118.

To form the active device, a gate dielectric layer 211 can be formed on the gate electrode 113. The gate dielectric layer 211 may be arranged to at least partly enclose the gate electrode 113. In FIG. 3b, the gate dielectric layer 211 can be provided at the interface to the drain electrode 112 and the source electrode 114, as well as on a vertical end surface of the gate electrode 113 (to the right in FIG. 3a). As further illustrated in FIG. 3b, the channel region can be formed by a channel layer 212 arranged on the dielectric layer 211. As mentioned above, the gate electrode 113 can be connected to the write word line, WWL, and used for arranging the write transistor in its closed or conducting state, in which a write voltage can be provided from the write bit line, WBL, connected to the source electrode 114 to the storage note, SN, formed by the drain electrode 112.

The gate electrode 116 can be formed by the same structure, or element, as the drain electrode 112 in FIG. 3a. The gate electrode 116 of the read transistor 115 and the drain electrode 112 of the write transistor 111 may hence extend in the same horizontal layer of the memory device 100, forming the charge storage node, SN, of the bit cell 110. The first source/drain electrode 117 can be connected to the read word line, RWL, whereas the second source/drain electrode 118 can be connected to the read bit line, RBL. In its closed or conducting state, the read transistor 115 may allow a read current to flow between the read word line, RWL, and the read bit line, RBL, thereby allowing charging or discharging of the read word line, RWL.

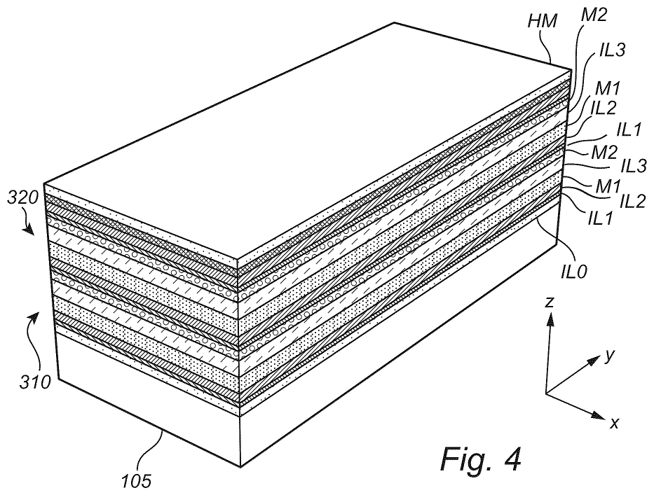

An exemplary process for forming the write and read transistors 111, 115 in FIGS. 3a and b, as well as a memory device 100 in FIG. 1, will now be disclosed with reference to FIGS. 4-15c, showing the result of various process modules.

FIG. 4 shows a semiconductor substrate 105 supporting a first and a second sub-stack 310, 320 of layers, into which the memory device is to be formed. In some examples, the first and second sub-stacks 310, 320 may be arranged on a peripheral device instead of a substrate 105. In the example of FIG. 4, the first bit cell 110 can be formed in the first sub-stack 310, whereas the second bit cell 120 can be formed in the second sub-stack 320, arranged above the first sub-stack 310. In the exemplary embodiment shown in FIG. 4, each sub-stack 310, 320 can include the following layers (in a bottom-top order): a first isolating layer structure IL1 of a SiCN layer on top of a SiN layer IL0, a second isolating layer IL2, a first conductive layer or metal layer M1 of Ru, and a third isolating layer structure IL3 of a a-Si layer and a TiN layer. Further, a second metal layer M2 can be formed above the third isolating layer structure IL3. Finally, a hard mask layer HM of, for example, Al₂O₃ can be arranged on top of the second sub-stack 320. It will be appreciated that this is an illustrating example of how to realize the inventive concept and that other materials and material combinations are also possible.

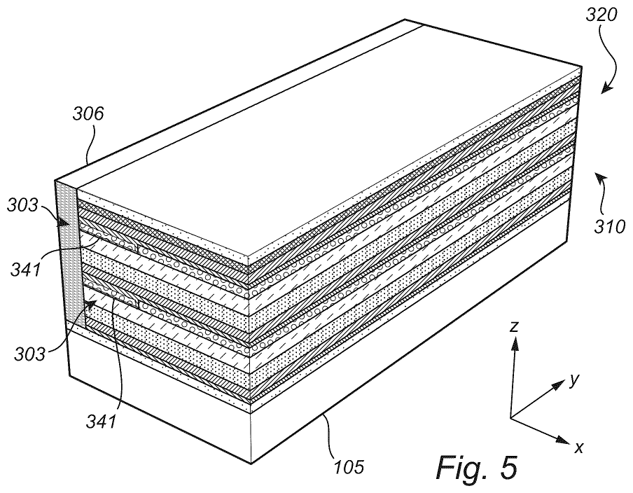

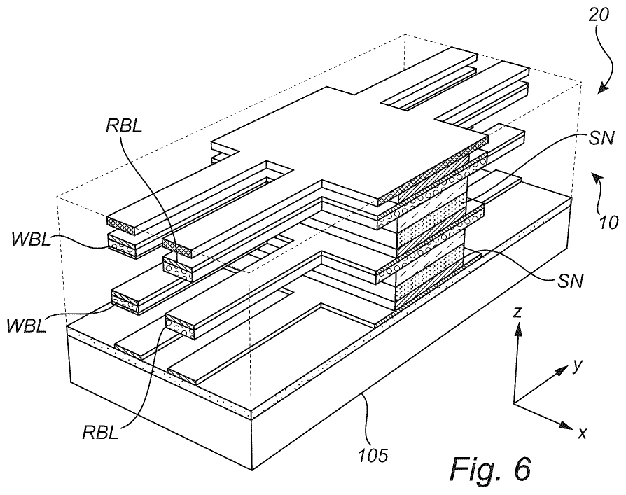

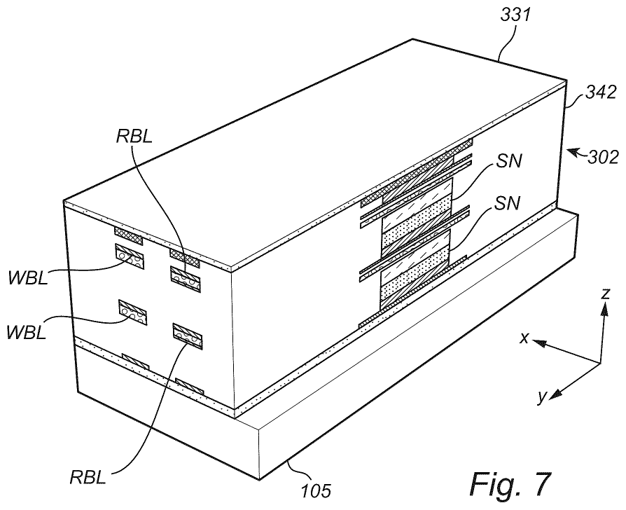

In FIG. 5, a vertical trench has been etched into the stacked layer structure through the first and second sub-stacks 310, 320. For each sub-stack 310, 320, the TiN barrier layer has been laterally recessed from the vertical trench to form a recess 303 that is lined with an insulating layer 341. In some examples, the TiN barrier layer may be replaced by the second metal layer M2. A metal barrier and fill layer may then be deposited on the insulating layer 341. The present processing module aims at isolating the future read bit lines, RBL, and write bit lines, WBL, extending horizontally along each sub-stack 310, 320 as indicated in e.g. FIGS. 6 and 7.

FIG. 6 shows the result of a processing module aiming at forming continuous metal lines along the y-axis, such as the read bit lines, RBL, and write bit lines, WBL, at each semiconductor device level. Further, the module aims at isolating the charge storage nodes, SN, of the bit cells, as well as layers that will be recessed later during the processing of the memory device.

In a first step, vertical trenches can be etched through the entire stack, that is, through the first and second sub-stacks 310, 320. The vertical trenches may, for example, be patterned using a dual patterning technique. Thereafter, the second metal layer M2, the third insulating layer IL3, and the first insulating layer IL1 can be laterally recessed to define the regions from which the charge storage nodes, SN, are to be formed. In the resulting structure shown in FIG. 6, each device level 10, 20 can include two parallel metal lines from which the read and write bit lines, RBL and WBL, are to be formed, as well as the layers from which the write and read transistor 111, 115 of each bit cell will be formed.

FIG. 7 is a rotated view, showing the side of the structure facing away from the viewer in FIG. 6. As shown in FIG. 7, the trenches and recesses can be filled with an isolating material 342, such as SiO2, and a vertical trench 302, similar to the vertical trench in FIG. 5, etched into the stacked layer structure, through the first and second sub-stacks 310, 320, using the mask layer 331 as an etch mask. The vertical trench 302 can be arranged to expose the sidewalls of the regions formed in FIG. 6, in which the write and read transistors 111, 115 are to be formed.

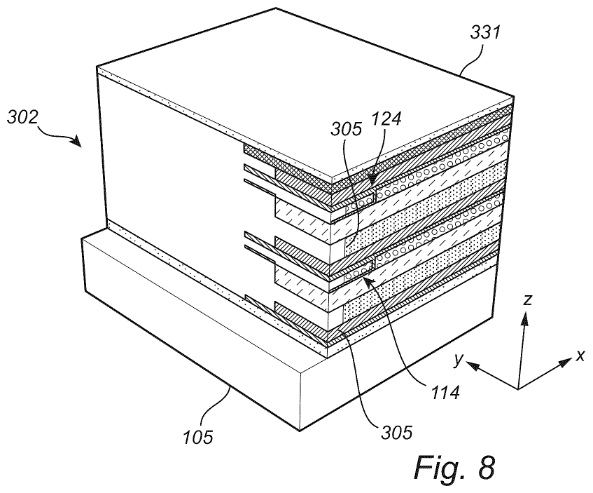

FIG. 8 is a perspective view of the structure as seen from the trench 302 and of a cross section taken through the y-axis. As shown in FIG. 8, the first metal layer M1 can be laterally recessed, followed by a deposition of an insulator 305, such as SiO2, and an etch-back process.

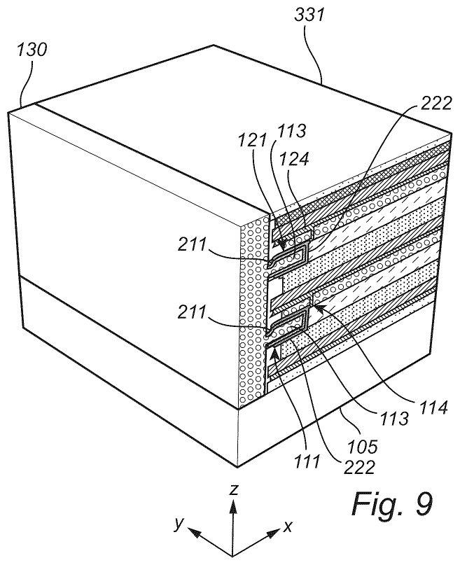

In FIG. 9, the third insulating layer IL3 can be recessed to form recesses in which the write transistors 111, 121 are defined by depositing the channel layer 212, the gate dielectric layer 211 and eventually the gate electrode 113. The gate electrode material can fill the remaining parts of the lined recesses 305 and also can form the interconnecting structure 130 extending vertically in the vertical trench, forming a common write word line, WWL, interconnecting the gate terminal 113, 123 of the write transistors of the first and second bit cells 110, 120.

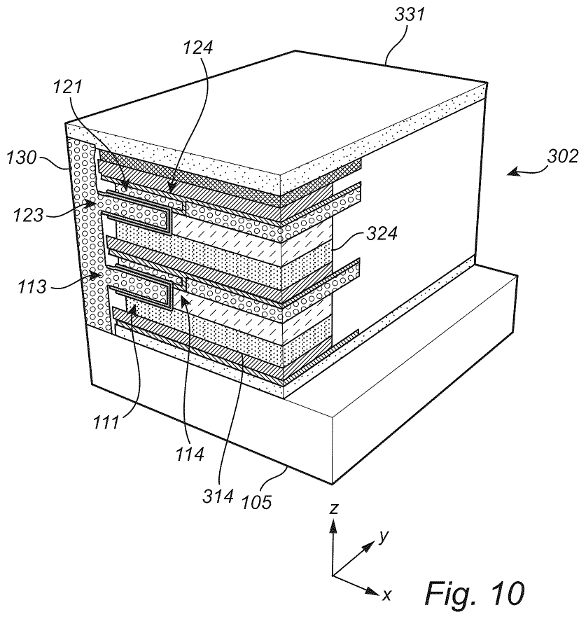

In FIG. 10, a second vertical trench 302, parallel to the trench in which the first interconnecting structure 130 is arranged, has been etched into the stacked structure to expose the sidewalls of the layers in which the read transistors 115, 125 are to be formed.

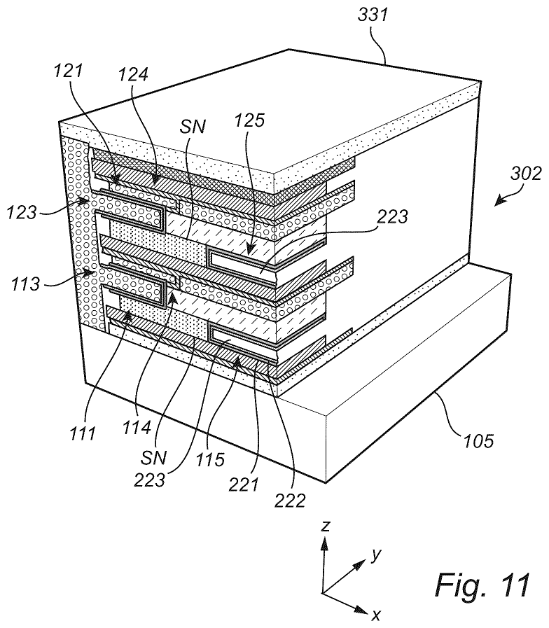

To form the read transistors 115, 125, the second vertical trench 302 can be used for forming lateral recesses in the Ru layer 314, arranged below the a-Si and SiCN layers in which the gate electrodes 113, 123 of the write transistors 111, 125 are formed on the opposite side of the stack, via the first vertical trench 301. A gate dielectric layer 221 and a channel layer 222 can be deposited in the recesses, which then can be filled with an isolating layer 223, such as SiO₂. The resulting structure is shown in FIG. 11.

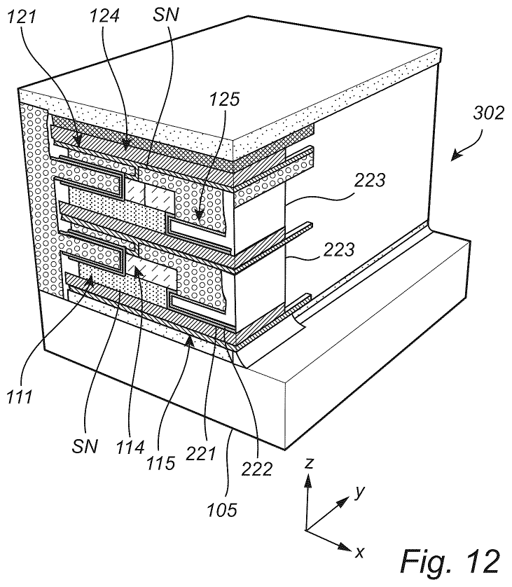

In FIG. 12, the second vertical trench 302 has been used to laterally recess the third insulating layer IL3 and etching the gate dielectric layer 221. A metallization coupled with a lateral metal recess can then be operated to form the source of the read transistor. Thereafter, after a filling and etch-back of an isolating material such as SiO₂ is performed to electrically isolate the source and drain of this read transistor. The drain of the read transistor is formed by a first lateral recessing of the second insulating layer IL2 followed by etching the gate dielectric layer 221 and a metallization process similar to the one forming the source, with the difference that no-etch back of the metal is performed in order to maintain a source-common vertical metal along the read transistors along the z-axis.

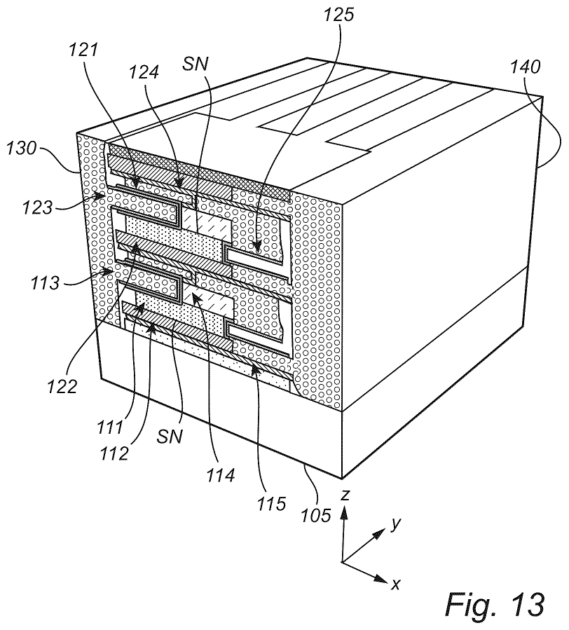

In FIG. 13, the SiN layer and the gate dielectric layer 221 have been laterally recessed, followed by a deposition of TiN to form the second interconnecting structure 140 extending vertically between the first and second read transistors 115, 125. As illustrated in FIG. 13 the two sub-stacks 310, 320 have now been processed to form a respective bit cell, each including a write transistor 111, 121 and a read transistor 115, 125. The gate electrodes 113, 123 of the write transistors 111, 121 can be interconnected by the vertically arranged interconnecting structure 130, whereas drain electrodes 112, 122 of the write transistors 111, 121 can be connected to the gate electrodes 116, 126 of the read transistors 115, 125 via the storage node, SN. A first one of the source/drain electrodes of the read transistors 115, 125 are, in turn, interconnected by the second interconnecting structure 140.

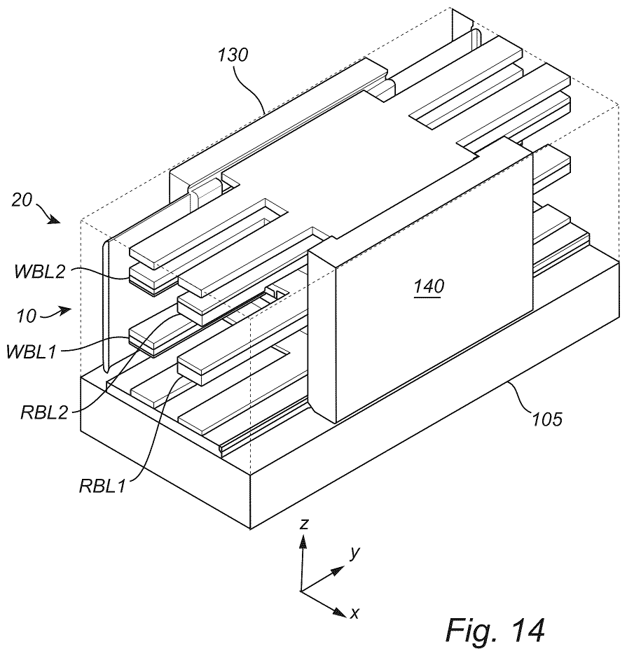

FIG. 14 is a perspective view of the memory device 100 formed in the above-described processing steps and modules. The first and second vertically oriented interconnecting structures 130, 140 are shown on opposite sides of the stacked bit cells, with respect to the x-axis. In the orthogonal direction, such as along the y-axis, the bit lines can be formed in the two semiconductor device layers 10, 20. The first write bit line, WBL1, and the first read bit line, RBL 1, extend in parallel in the first semiconductor device level 10, whereas the second write bit line, WBL2, and the second read bit line, RBL 2, can be arranged between each other in the second semiconductor device layer 20.

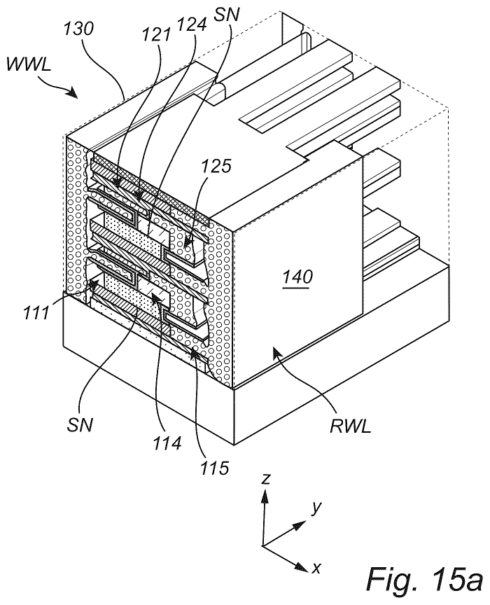

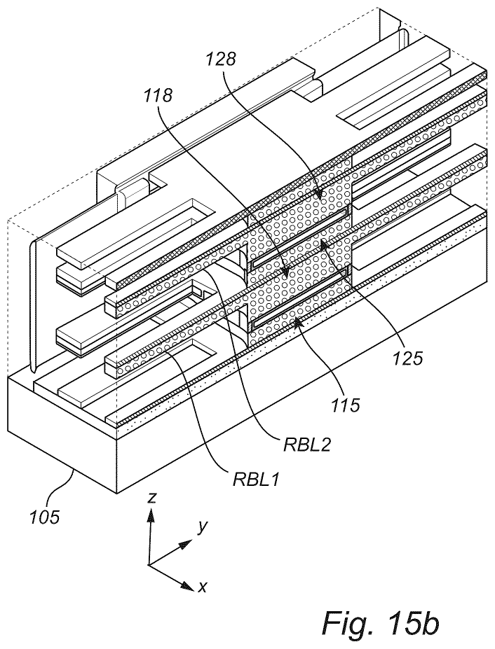

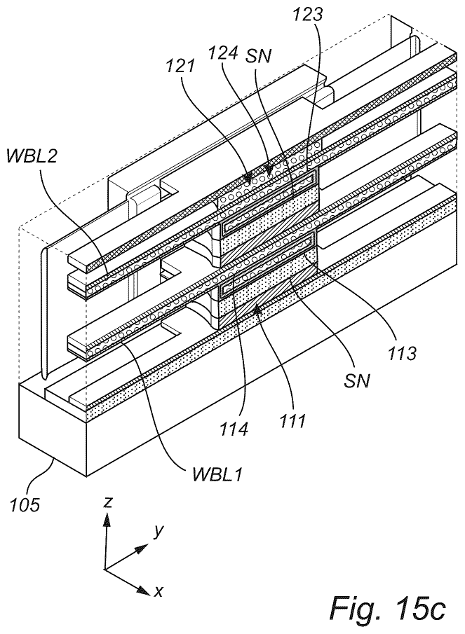

FIGS. 15a-c show different cross sections of the memory device 100 in FIG. 14. FIG. 15a is a cross section through the y-axis, showing the orientation of the first and second write transistors 111, 121 in relation to the first and second read transistors 115, 125 and the storage node, SN, defined therebetween. The first interconnecting structure 130 forms the write word line WWL, which hence is common to both write transistors 111, 121 of the stacked bit cells. In a trench opposite the first interconnecting structure 130, the second interconnecting structure 140 is arranged, forming the read word line, RWL, which is common to the two read transistors 115, 125 of the memory device 100.

FIG. 15b is a cross section through the x-axis and the read transistors 115, 125, illustrating the first and second read bit lines, RBL 1, RBL2, which are vertically separated from each other and extending horizontally along the y-axis. The first read bit line, RBL 1 can be connected to a source/drain electrode 118 of the first read transistor 115, whereas the second read bit line, RBL 2, can be connected to a source/drain electrode 128 of the second read transistor 125.

FIG. 15c is a similar cross section as in FIG. 15b, taken through the write transistors 111, 121 instead. As shown in FIG. 15c, the first and second write bit lines, WBL 1 and WBL2, are illustrated, extending horizontally along the y-axis and being vertically isolated from each other. The first write bit line, WBL1, can be connected to source/drain electrode 114, such as the source of the first write transistor 111, and the second write bit lines, WBL 2, to the source electrode 124 of the second write transistor 121. Further, a cross section of the storage node, SN, can also be shown, arranged below the source electrode 114, 124 and the gate electrode 113, 123 of the write transistors 111, 121.

While the disclosed technology has been illustrated and described in detail in the drawings and foregoing description, such illustration and description are to be considered illustrative or exemplary and not restrictive. Other variations to the disclosed embodiments can be understood and effected by those skilled in the art in practicing the disclosed technology. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage.

What is claimed is:

1. A memory device configured as a dynamic random-access memory, the memory device comprising:
a substrate supporting a first semiconductor device layer comprising a first bit cell;
a second semiconductor device layer comprising a second bit cell,
wherein the first semiconductor device layer is arranged vertically between the substrate and the second semiconductor device layer,
wherein each of the first and second bit cells includes a write transistor and a read transistor, and
wherein a first source/drain terminal of the write transistor is connected to a gate of the read transistor to form a storage node of the each of the first and second bit cells,
a first interconnecting structure extending vertically between the first and second semiconductor device layers and being arranged to form a write word line common to gate terminals of the write transistors of the first and second bit cells; and
a second interconnecting structure extending vertically between the first and second semiconductor device layers and being arranged to form a read word line common to first source/drain terminals of the read transistors of the first and second bit cells.

2. The memory device according to claim 1, wherein each of the first and second semiconductor device layer comprises a plurality of bit cells and a horizontal read bit line interconnecting a second source/drain terminal of the read transistors of each of the first and second bit cells.

3. The memory device according to claim 2, wherein each of the first and second semiconductor layers further comprises a horizontal write bit line interconnecting the second source/drain terminal of the write transistors of each bit cell.

4. The memory device according to claim 2, wherein the read bit line of the first semiconductor device layer is electrically insulated from the read bit line of the second semiconductor device layer.

5. The memory device according to claim 3, wherein the write bit line of the first semiconductor device layer is electrically insulated from the write bit line of the second semiconductor device layer.

6. The memory device according to claim 1, wherein the write transistor and the read transistor are metal-oxide semiconductor field-effect transistors.

7. The memory device according to claim 1, wherein:
the first bit cell is formed in a first sub-stack of layers and the second bit cell is formed in a second sub-stack of layers;
for each of the first and second sub-stacks, the first source/drain terminal of the write transistor is formed in a same layer of a respective one of the sub-stacks as the gate of the read transistor;
the write word line is arranged in a first trench, extending vertically into the first and second sub-stacks, to electrically interconnect the gate terminal of the write transistors of the first and second bit cells; and
the read word line is arranged in a second trench, extending vertically into the first and second sub-stacks and being parallel to the first trench, to electrically interconnect the first source/drain terminal of the read transistors of the first and second bit cells.

8. A method for forming a memory device configured as a dynamic random-access memory, the memory device comprising a first bit cell and a second bit cell, each of the first and second bit cells comprising a write transistor and a read transistor, wherein a first source/drain terminal of the write transistor is connected to a gate of the read transistor to form a storage node of the bit cell, the method comprising:
forming a first trench and a second trench, parallel to the first trench, in a stacked layer structure comprising a first sub-stack and a second sub-stack of layers;
in the first trench, forming the write transistor of each of the first and second sub-stacks by laterally recessing layers of the each of the first and second sub-stacks and forming, in the recesses, a channel structure, a gate dielectric and gate metal of the write transistor;
forming a write word line in the first trench to interconnect the gate terminal of the write transistors of the first and second bit cells;
in the second trench, forming the read transistor of each of the first and second sub-stacks by laterally recessing layers of the each of the first and second sub-stacks and forming, in the recesses, a channel structure and a gate dielectric of the read transistor, and an isolating layer; and
forming the read word line in the second trench to interconnect the first source/drain terminal of the read transistor of the first and second bit cells.

9. The method according to claim 8, further comprising:
for each of the first and second sub-stacks, forming a first lateral recess from the first trench and a second lateral recess from the second trench;
filling the first lateral recess with a conductive material to form a horizontal read bit line for connecting the read transistor; and
filling the second lateral recess with a conductive material to form a horizontal write bit line for connecting the write transistor.

10. The method according to claim 9, wherein:
each of the first and second sub-stacks comprises a plurality of bit cells;
the horizontal read bit line is arranged to interconnect the read transistors of each of the plurality of bit cells; and
the horizontal write bit line is arranged to interconnect the write transistors of each of the plurality of bit cells.
